(19) United States
(12) Patent Application Publication
(10) Pub. No.: US 2004/0103844 A1
(43) Pub. Date: Jun. 3, 2004

(54) [GAS DISTRIBUTING SYSTEM FOR DELIVERING PLASMA GAS TO A WAFER REACTION CHAMBER]

(76) Inventors: Chung-Yen Chou, Taipei (TW); Yu-Chung Tien, Yunlin Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,392

(22) Filed: Jul. 17, 2003

(30) Foreign Application Priority Data
Oct. 18, 2002 (TW) 91124147

(51) Int. Cl. H01L 21/306; C23C 16/00

(52) U.S. Cl. 118/715; 156/345.29; 156/345.34

(57) ABSTRACT

A gas distributing system and a method of operating the distributing system is provided. After setting a few control valve parameters, the gas distributing system automatically adjusts the distribution of plasma gas inside a wafer processing chamber during a dry etching or a film deposition process so that uniform single wafer is produced. First, a main gas conduit is redirected into two separate gas conduit inside a gas separator. One conduit connects with a gas nozzle near the central region of an upper electrode panel distributor and the other conduit connects with a gas nozzle near the peripheral region of the upper electrode panel distributor. An O-ring between the central region and the peripheral region prevents any mixing of gas from the nozzles in these two regions. Gas distribution inside the reaction chamber can be changed to meet the need of different processing conditions by adjusting the flow control valves mounted on the two conduits.

### CROSS REFERENCE TO RELATED APPLICATIONS

This application claims the priority benefit of Taiwan application serial no. 91124147, filed Oct. 18, 2002.

### BACKGROUND OF INVENTION

1. Field of Invention

The present invention relates to a gas distributing system for controlling a flow of plasma gas into a reaction chamber. More particularly, the present invention relates to a gas distributing system having a set of flow control valves for adjusting flow parameters so that the distribution of plasma inside the reaction chamber is optimized to produce the best etching or deposition a wafer can receive.

2. Description of Related Art

As the fabrication of sub-micron integrated circuits (IC) matures, the size of a raw wafer is also increased (from 8 inches to 12 inches). To fabricate high quality wafers, the distribution of plasma gas inside a reaction chamber must be properly controlled. Since single wafer reaction chamber has many advantages, plasma etching or thin film deposition is often carried out inside such chambers. However, the distribution of plasma gas inside the reaction chamber is an important factor that determines the ultimate quality of the processed wafer.

A conventional semiconductor processing, such as wafer dry etching or plasma etching or thin film deposition, is achieved through reaction of gaseous chemicals delivered to the surface of a wafer via a gas distribution system into a reaction chamber 100 as shown in FIG. 1. Gas running inside a delivering pipe 102 is partially separated through a gas nozzle 104 before passing into the reaction chamber 100 through an upper electrode panel showerhead 106. FIG. 2 is a top view of the upper electrode panel showerhead 106. The showerhead 106 includes an array of uniformly distributed gas holes 108 for distributing gaseous reactants uniformly to each corner of the reaction chamber 100. However, in the plasma etching or thin film deposition process, etching or deposition thickness may vary somewhat according to local processing parameters (including, type of gaseous reactants, temperature, pressure and etching or depositing height). For example, the amount of processing received by the central area of wafer may differ from the peripheral area by up to 30%. In general, parameters including temperature and pressure can be directly and precisely adjusted through the semiconductor processing station. Yet, the distribution of plasma gas inside the reaction chamber 100 can only be achieved by re-designing of the pattern of gas holes 108 on the upper electrode panel showerhead 106. To prevent any variation of process parameters between the central region and the peripheral region of a wafer after an etching or material deposition process, an upper electrode panel showerhead with a properly patterned set of holes must be selected to reflect the actual fabricating conditions. However, the processing station needs to shut down before changing the showerhead. This not only slows down the utilization of the processing station but also increases the production cost.

### SUMMARY OF INVENTION

Accordingly, one object of the present invention is to provide a gas distributing system for distributing plasma gas inside a wafer reaction chamber in such a way that a wafer inside the reaction chamber is uniformly processed.

Another object of this invention is to provide a gas distributing system having a setting for adjusting the flow of plasma gas inside a reaction chamber so that the same degree of uniformity can be achieved for a wafer undergoing different fabrication process.

Another object of this invention is to provide a method of monitoring and automatically adjusting the flow of gas plasma from a gas pipeline to a reaction chamber according to the setting of a particular fabrication process.

To achieve these and other advantages and in accordance with the purpose of the invention, as embodied and broadly described herein, the invention provides a gas distributing system for delivering plasma gas to the gas reaction chamber of a semiconductor wafer processing station. The gas distribution system includes a main gas distribution conduit linked to a gas separator having a first and a second gas distribution conduit, a first flow control valve along the first gas distribution conduit for controlling the flow of gas through the first gas distribution conduit, a second flow control valve along the second gas distribution conduit for controlling the flow of gas through the second gas distribution conduit, a first nozzle and a second nozzle located at the outlet of the first and the second gas distribution conduit, a gas barrier between the first and the second nozzle for isolating the gas passing out from the first and the second nozzle, and an upper electrode panel distributor having a first set of gas holes and a second set of gas holes such that gas from the first nozzle is output to the reaction chamber via the first set of gas holes and the gas from the second nozzle is output to the reaction chamber via the second set of gas holes.

The aforementioned gas distribution system further includes a control system having a controller for controlling the first and the second flow control valves and a first and a second gas flow detector located along the first and the second gas distribution conduit for detecting the volume flow rate of gas inside the first and the second gas distribution conduit and sending corresponding signals to the controller.

In the embodiment of this invention, the gas flow detector includes a heated coil and the flow control valve includes a manually adjustable valve. The first set of gas holes is located in the central region of the upper electrode panel distributor and the second set of gas holes is distributed in the peripheral region of the upper electrode panel distributor. The gas barrier includes O-rings made from rubber or plastic material. The O-rings may also be fabricated using a corrosion resistant material including Teflon. The first set of gas holes is positioned evenly on the upper electrode panel distributor and the second set of gas holes is position evenly on the upper electrode panel distributor.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic side view showing a conventional gas distribution system atop a wafer reaction chamber.

FIG. 2 is a top view showing the distribution of gas holes on a conventional upper electrode panel distributor.

FIG. 3 is a schematic side view showing a gas distribution system atop a wafer reaction chamber according to one preferred embodiment of this invention.

FIG. 4 is a cross-sectional view showing vias for connecting different metallic layers inside a wafer.

FIG. 5 is a diagram showing the internal construct of a gas separator of the gas distribution system according to a first embodiment of this invention.

FIG. 6 is a circuit showing a conventional Whetstone bridge structure.

FIG. 7 is a flow chart showing the steps for operating the gas distribution system according to this invention.

FIG. 8 is a diagram showing the internal construct of a gas separator of the gas distribution system according to a second embodiment of this invention.

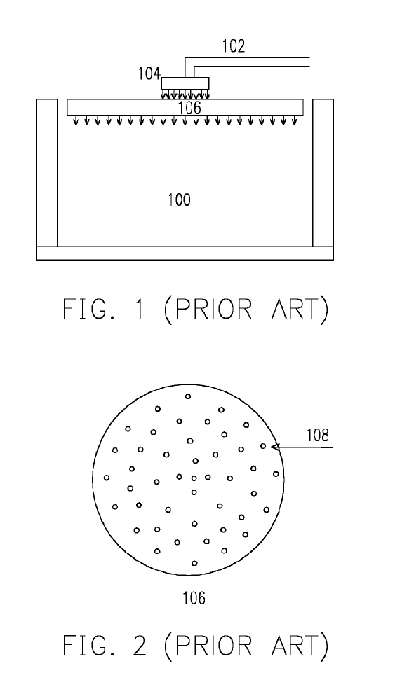

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

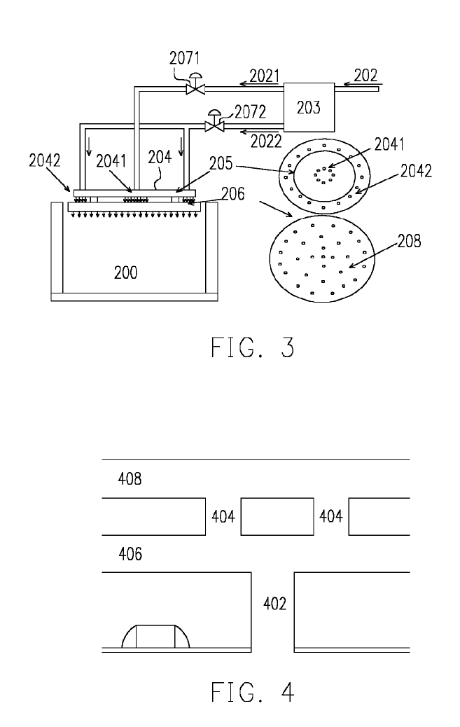

FIG. 3 is a schematic side view showing a gas distribution system atop a wafer reaction chamber according to a preferred embodiment of the present invention. The plasma gas reaction station in FIG. 3 includes a main gas distribution conduit 202 and a reaction chamber 200. The gas distribution conduit 202 for delivering gas into the reaction chamber 200 first joins up with a gas separator 203. The gas separator 203 has two separate output conduits 2021 and 2022. The conduit 2021 is connected to a set of gas nozzles 2041 close to the central region of a top plate 204 and the conduit 2022 is connected to a set of gas nozzles 2042 distributed around the peripheral region of the top plate 204. Gas from the gas nozzles 2041 is prevented from mixing with gas from the gas nozzles 2042 through an O-ring 205 in the top plate 204 above an upper electrode panel distributor 206. A pair of flow control valves 2071 and 2072 controls the gas flow rate through the pipelines 2021 and 2022 respectively. By controlling the flow of gas through the conduits 2021 and 2022, distribution of gas inside the reaction chamber 200 after going through the gas holes 208 on the upper electrode panel distributor 206 can be tuned to whatever processing conditions one demands. The O-ring 205 can be fabricated using elastic material including rubber or plastic if the plasma gas used for the reaction is non-corrosive. However, if the plasma gas is corrosive, the O-ring 205 must be fabricated using a corrosion-resistant substance including, for example, Teflon.

FIG. 4 is a cross-sectional view showing the fabrication of vias (via1 402 and via2 404) for connecting different metallic layers inside a wafer by plasma etching. Although the gaseous etchant used for the etching operation is C1₂ or BC1₃, a first metallic layer (Metal1) 406 and a second metallic layer (Metal2) 408 have different thickness. Therefore, if the same etching parameters for etching the first metallic layer 406 is used to etch the second metallic layer 408, the degree of etching between a central portion and a peripheral portion of the wafer may differ so much that an acceptable limit is exceeded. On the other hand, if the flow control valves along the gas distribution conduit 202 is adjusted to change the flow rate of gas to the centrally located nozzles 2041 and peripherally located nozzles 2042, the distribution of plasma gas inside the reaction chamber 200 will also change. Ultimately, difference between central and peripheral portion of a wafer due to etching may be reduced. With the gas distribution system of this invention installed atop the reaction chamber 200, there is no need to dissemble and install another upper electrode panel distributor 206 for each new wafer processing operation.

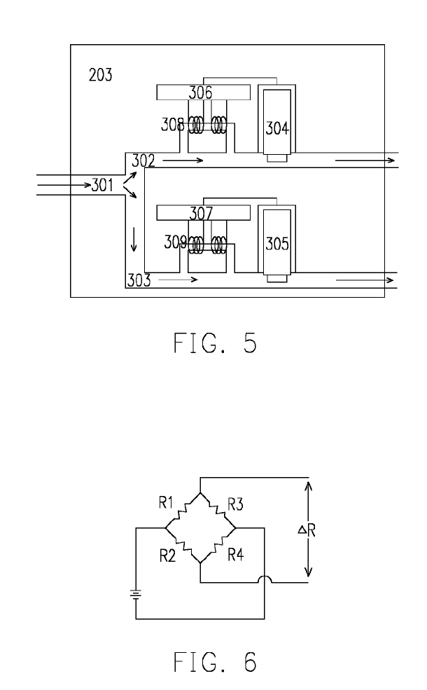

FIG. 5 is a diagram showing a preferred embodiment of an internal construct of the gas separator according to the first embodiment of this invention. As shown in FIG. 5, the gas separator 203 includes an inflow gas conduit 301 and two outflow gas conduits 302 and 303, gas control valves 304, 305 along the gas conduits 302 and 303, and control circuits 306, 307 for controlling the control valves 304 and 305 respectively. For example, as gas from a gas supply is passed into the conduit 301, the gas branches out into two streams. One stream goes into the conduit 302 while the other stream goes into the conduit 303. Each gas conduit (302 or 303) has a corresponding gas flow detector 308 or 309 that monitors the gas flow rate and feeds back a signal to a main control system for comparing with a reference value. If there are any discrepancies between the feedback signal and the reference value, the main control system may send a signal to the gas control valves (304 and 305) to adjust the flow rate inside the conduits 302 and 303. Hence, the flow rate between the two conduits can be set to whatever ratio one desired. The gas flow detectors 308 and 309 can be heated coils, for example. Gas passing by a heated coil will carry heat away and hence the amount of heat carried away depends on the gas flow rate. Any change in the temperature will alter the resistant of the coil. The control circuits 306 and 307 for controlling the valves (304 and 305) can have a Whetstone bridge structure as shown in FIG. 6. A gas flow rate inside the conduits (302 and 304) can be determined by monitoring the resistance in heated coils. With suitable calibrations, the gas flow rate inside the conduits 302 and 303 can be set to any desired values by adjusting the control valves 304 and 305.

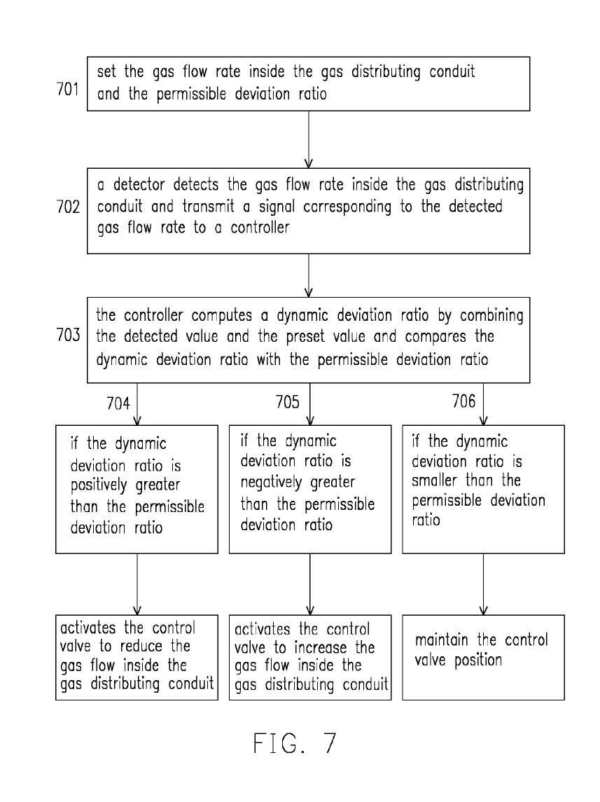

FIG. 7 is a flow chart showing steps for operating the gas distribution system according to this invention. First, a gas flow rate inside the gas distributing conduits and permissible deviation ratio of the volume flow ratio is determined according to a specified wafer processing operation (in step 701). Thereafter, the actual gas flow rate inside the conduits is detected and then the detected values are returned to the control system (in step 702). The control system computes a dynamic deviation ratio by combining the detected value and the preset value and then compares the dynamic deviation ratio with the permissible deviation ratio (in step 703). If the dynamic deviation ratio is positively greater than the permissible deviation ratio, a signal from the control system is sent to the control valve for reducing the gas flow rate inside the conduit (in step 704). However, if the dynamic deviation ratio is negatively greater than the permissible deviation ratio, a signal from the control system is sent to the control valve for increasing the gas flow rate inside the conduit (in step 705). If the dynamic deviation ratio is smaller than the permissible deviation ratio, this indicates that the gas flow rate inside the conduit is normal. Under this condition, the control system no longer sends any signal to the control valve to adjust the gas flow (in step 706).

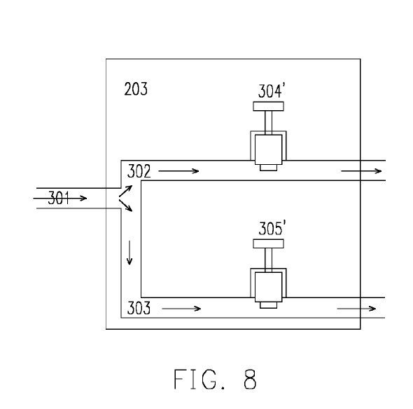

FIG. 8 is a diagram showing the internal construct of a gas separator of the gas distribution system according to a second embodiment of this invention. The gas separator 203 in FIG. 8 includes gas conduits 301, 302, 303 and flow control valves 304″ and 305″. Similar to the first embodiment, gas flowing into the main conduit 301 branches out into two streams, one going to the conduit 302 and another going to the conduit 303. The flow control valves 304″ and 305″ along the conduits 302 and 303 are manually controlled valves. Unlike the first embodiment that includes detectors (308 and 309) for monitoring the gas flow inside the conduits (302 and 303) and control circuits (306 and 307) for adjusting valve positions, the second embodiment only includes two manually operated valves (304″ and 305″) to reduce production cost. Nevertheless, the desired plasma gas distribution can still be obtained without changing any hardware inside the reaction chamber even in the absence of any control circuits and detectors.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A gas distributing system for delivering gaseous reactant to a reaction chamber during a wafer fabrication process, comprising:
a main gas distributing conduit branching out to a first gas distributing conduit and a second gas distributing conduit;
a first flow control valve along the first gas distributing conduit for controlling the gas flow rate inside the first gas distributing conduit;
a second flow control valve along the second gas distributing conduit for controlling the gas flow rate inside the second gas distributing conduit;
a top plate having a first gas nozzle at the outlet of the first gas distributing conduit, a second gas nozzle at the outlet of the second gas distributing conduit, and a gas barrier disposed in the top plate between the first gas nozzle and the second gas nozzle for preventing the mixing of gas from the first gas nozzle and the second gas nozzle; and
an upper electrode panel gas distributor having a first set of gas holes and a second set of gas holes thereon, wherein gas from the first gas nozzle passes into the reaction chamber through the first set of gas holes and gas from the second gas nozzle passes into the reaction chamber through the second set of gas holes.

2. The gas distributing system of claim 1, wherein the system further includes a control system having:
a controller for adjusting the first flow control valve and the second flow control valve;
a first gas flow detector along the first gas distributing conduit for detecting the gas flow rate inside the first gas distributing conduit and sending back a signal corresponding to the detected gas flow rate to the controller; and
a second gas flow detector along the second gas distributing conduit for detecting the gas flow rate inside the second gas distributing conduit and sending back a signal corresponding to the detected gas flow rate to the controller.

3. The gas distributing system of claim 2, wherein the first gas flow detector comprises a heated coil, and the second gas flow detector comprises a heated coil.

4. The gas distributing system of claim 1, wherein the first flow control valve comprises a manually adjustable valve, and the second flow control valve comprises a manually adjustable valve.

5. The gas distributing system of claim 1, wherein the first gas nozzle is positioned somewhere near the central region of the upper electrode panel distributor, and the second gas nozzle is positioned somewhere near the peripheral region of the upper electrode panel distributor.

6. The gas distributing system of claim 1, wherein the gas barrier comprises an O-ring.

7. The gas distributing system of claim 6, wherein the O-ring is fabricated using a material comprising elastic material.

8. The gas distributing system of claim 6, wherein the O-ring is fabricated using a corrosion-resistant material.

9. The gas distributing system of claim 8, wherein the corrosion-resistant material comprises Teflon.

10. The gas distributing system of claim 1, wherein the first set of gas holes on the upper electrode panel distributor is evenly spaced.

11. The gas distributing system of claim 1, wherein the second set of gas holes on the upper electrode panel distributor is evenly spaced.

12. A method of distributing gaseous reactant to the reaction chamber of a semiconductor wafer processing station, comprising the steps of:
setting two gas flow rates inside a first and a second gas distributing conduits and two permissible deviation ratios of the two gas flow rates respectively;
detecting the gas flow rates inside the first and the second gas distributing conduits and returning two signals corresponding to the gas flow rates to a control system respectively;
computing two dynamic deviation ratios by comparing the gas flow rate inside the first and the second gas distributing conduits with the preset gas flow rates of both conduits respectively;
comparing the dynamic deviation ratios of the first and the second gas distributing conduits with the permissible deviation ratios of both conduits respectively, and
providing two control signals from the control system for informing the control valves on the first and the second gas distributing conduits to adjust the gas flow rates inside the first and the second gas distributing conduits.

13. The method of claim 12, wherein the steps of providing two control signals from the control system for informing the control valves, if the dynamic deviation ratio of the first distributing conduit is positively greater than the permissible deviation ratio of that, the control signal for informing the control valve on the first gas distributing conduit is to reduce the gas flow rate inside the first gas distributing conduit.

14. The method of claim 12, wherein the steps of providing two control signals from the control system for informing the control valves, if the dynamic deviation ratio of the second distributing conduit is positively greater than the permissible deviation ratio of that, the control signal for informing the control valve on the second gas distributing conduit is to reduce the gas flow rate inside the second gas distributing conduit.

15. The method of claim 12, wherein the steps of providing two control signals from the control system for informing the control valves, if the dynamic deviation ratio of the first distributing conduit is negatively greater than the permissible deviation ratio of that, the control signal for informing the control valve on the first gas distributing conduit is to increase the gas flow rate inside the first gas distributing conduit.

16. The method of claim 12, wherein the steps of providing two control signals from the control system for informing the control valves, if the dynamic deviation ratio of the second distributing conduit is negatively greater than the permissible deviation ratio of that, the control signal for informing the control valve on the second gas distributing conduit is to increase the gas flow rate inside the second gas distributing conduit.
